(19) United States
(12) Patent Application Publication
(10) Pub. No.: US 2026/0181817 A1
(43) Pub. Date: Jun. 25, 2026

(54) DISPLAY DEVICE

(71) Applicant: Qisda Corporation, Taoyuan City (TW)

(72) Inventor: TAI-YU KUO, Taoyuan City (TW)

(73) Assignee: Qisda Corporation, Taoyuan City (TW)

(21) Appl. No.: 19/289,736

(22) Filed: Aug. 4, 2025

(30) Foreign Application Priority Data
Dec. 20, 2024 (CN) 202411896126.1

(51) Int. Cl. H05K 7/20; G06F 1/16; G06F 1/20; G06F 3/0354

(52) U.S. Cl. CPC H05K 7/20145; G06F 1/1601; G06F 1/20; G06F 3/03545; H05K 7/20172; H05K 7/20209; H05K 7/20972

(57) ABSTRACT

A display device is disclosed. The display device includes a display panel, a rear housing, a fan, and a flow-guiding structure. The rear housing is positioned on a rear side of the display panel; the rear housing and the display panel together define an internal region therebetween. The rear housing also has an air inlet and an air outlet. The fan is positioned within the internal region and close to the air inlet or the air outlet, which is configured to drive air to flow through the air inlet and the air outlet, forming an airflow pathway between the air inlet and the air outlet. The flow-guiding structure is movably positioned within the internal region and along the airflow pathway, wherein the flow-guiding structure is configured to move to allow air to selectively flow through a portion of the airflow pathway.

### CROSS REFERENCE TO RELATED APPLICATION

This application claims the priority benefit of China Patent Application No. 202411896126.1, filed on December 20, 2024. The entirety of the mentioned above patent application is hereby incorporated by reference herein and made a part of this specification.

### BACKGROUND OF THE INVENTION

### 1. Field of the invention

The present invention relates to a display device, more specifically to a display device having an adjustable flow-guiding structure.

### 2. Description of the prior art

In recent years, display devices are widely applied in various electronic products, including televisions, computer monitors, billboards, tablets, smartphones, touch screens, and drawing tablets. To ensure that display devices operate at normal temperatures and enhance user comfort, cooling mechanisms such as fans are typically employed to effectively dissipate heat generated by internal components like circuits and light sources.

However, the temperatures within different areas of a display device are not uniform and may be affected by many factors such as component layout, usage habits, environmental heat sources, and airflow direction. This can lead to higher temperatures and greater cooling demands in specific areas. Conventional display devices typically feature a single cooling mode, providing overall uniform cooling but lacking the capability to enhance cooling for specific areas.

Therefore, there is a need to develop display devices with adjustable cooling modes corresponding to various cooling demands, thereby improving device performance and user experience.

### SUMMARY OF THE INVENTION

An objective of the present invention is to provide a display device having an adjustable flow-guiding structure, wherein the flow-guiding structure is configured to move to allow air to selectively flow through a portion of the airflow pathway, achieving zoned cooling for the display device.

To achieve the above objectives, the present invention provides a display device includes a display panel, a rear housing, a fan, and a flow-guiding structure. The rear housing is positioned on a rear side of the display panel; the rear housing and the display panel together define an internal region therebetween. The rear housing also has an air inlet and an air outlet. The fan is positioned within the internal region and close to the air inlet or the air outlet, which is configured to drive air to flow through the air inlet and the air outlet, forming an airflow pathway between the air inlet and the air outlet. The flow-guiding structure is movably positioned within the internal region and along the airflow pathway, wherein the flow-guiding structure is configured to move to allow air to selectively flow through a portion of the airflow pathway; or, the flow-guiding structure is movably positioned within the internal region and is configured to move to alter the airflow pathway.

Compared to current technology, the display device provided by the present invention is capable of directing and concentrating airflow to pass through specific areas requiring heat dissipation enhancement, thereby achieving effective zoned cooling. The display device provided by the present invention can also be equipped with a sensor to adjust the rotation speed of the fan to achieve optimal cooling, thereby reducing noise and energy consumption and improving user experience.

### BRIEF DESCRIPTION OF THE DRAWINGS

FIG. 1 is a schematic diagram of the display device in an embodiment of the present invention.

FIG. 2 is a schematic diagram of the display device in another embodiment of the present invention.

FIG. 3A and 3B are a partial schematic view and an overall schematic view, respectively, of the display device in another embodiment of the present invention.

FIG. 4 is a partial schematic view of the display device in another embodiment of the present invention.

FIGS. 5A and 5B are partial side sectional diagrams of the display device under different operating conditions.

FIGS. 6A and 6B are a partial side sectional view and an overall schematic view, respectively, of the display device in an operation state of another embodiment of the present invention; FIGS. 7A and 7B are a partial side sectional view and an overall schematic view, respectively, of the display device in another operation state of the same embodiment; FIGS. 8A and 8B are a partial side sectional view and an overall schematic view, respectively, of the display device in another operation state of the same embodiment.

FIG. 9 is a schematic diagram of the display device in another embodiment of the present invention.

FIG. 10 is a schematic diagram of the display device in another embodiment of the present invention.

### DETAILED DESCRIPTION OF THE INVENTION

To provide a further understanding of the objectives, structures, features, and functions of the present invention, various embodiments and accompanying drawings will be described below to illustrate the implementation of the present invention. In the accompanying drawings, the thicknesses of layers, films, panels, areas, etc. are exaggerated for clarity. Throughout this specification, the same reference signs denote the same elements. It should be understood that when an element is referred to as being "on" or "connected to" another element, it may be directly on or connected to the another element, or there may be other elements therebetween. On the contrary, when an element is referred to as being "directly on" or "directly connected to" another element, there is no element therebetween. As used herein, "connection" may refer to a physical and/or electrical connection.

Certain terminology is used in the specification and claims to refer to specific components. A person having ordinary skill in the art should understand that manufacturers may use different terms to refer to the same component. The present specification and claims do not differentiate components based on the variation in nomenclature, but rather on their functional differences. The term "include" mentioned throughout the specification and claims is an open-ended phrase, therefore, it should be interpreted as "including but not limited to".

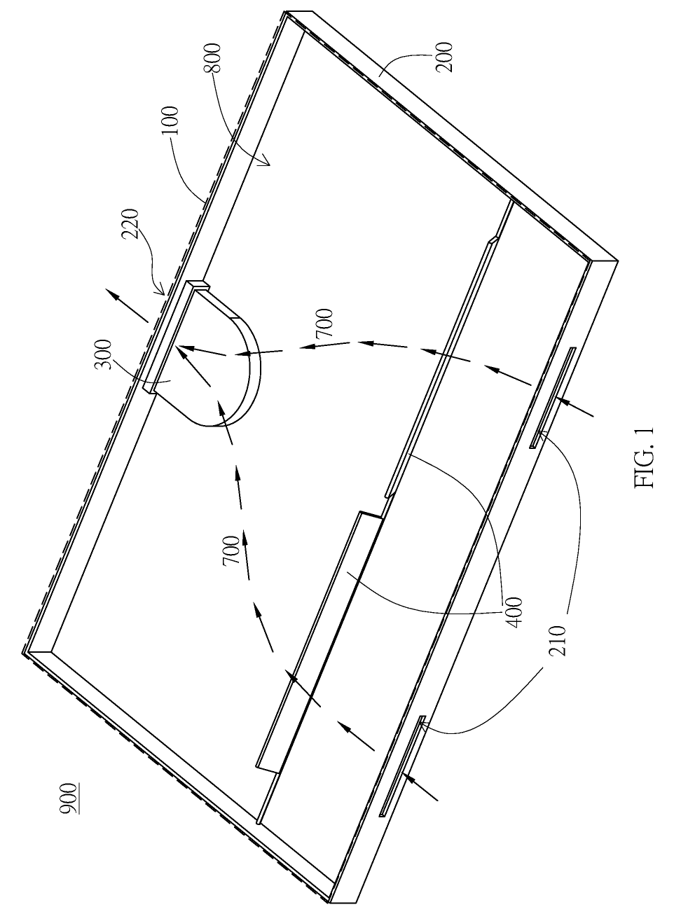

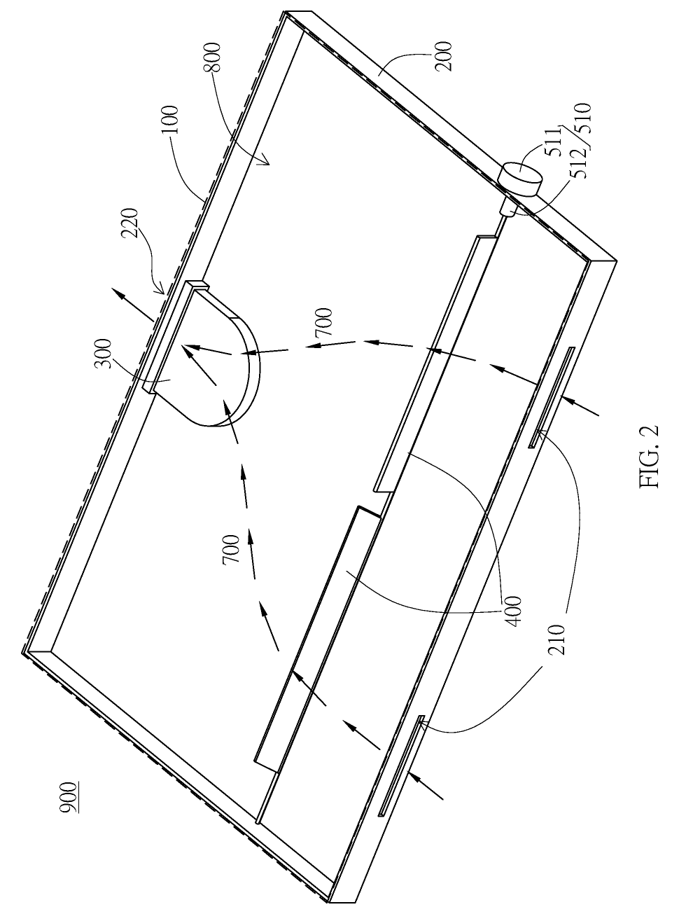

As shown in FIG. 1, the display device in an embodiment of the present invention includes a display panel 100, a rear housing 200, a fan 300, and a flow-guiding structure 400. Wherein the rear housing 200 is positioned on a rear side of the display panel 100; the rear housing 200 and the display panel 100 together define an internal region 800 therebetween. The rear housing 200 also has an air inlet 210 and an air outlet 220. The fan 300 is positioned within the internal region 800 and close to the air inlet 210 or the air outlet 220, wherein the fan 300 is configured to drive air to flow through the air inlet 210 and the air outlet 220, forming an airflow pathway 700 between the air inlet 210 and the air outlet 220. The flow-guiding structure 400 is movably positioned within the internal region 800 and along the airflow pathway 700.

Specifically, the display device 900 may be a display monitor, a touch screen, a television, a handwriting pad or drawing tablet with display functionality, and the like, but not limited thereto. The display panel 100 may be a liquid-crystal display (LCD) panel, an organic light-emitting diode (OLED) display panel, an inorganic light-emitting diode (LED) display panel, a quantum dot light-emitting diode (QLED) display panels, electro-phoretic display (EPD) panel, or other suitable display panel, but not limited thereto.

The rear housing 200 is positioned on the rear side of the display panel 100, and the rear housing 200 and the display panel 100 together define the internal region 800 therebetween for accommodating components of the display device 900. Furthermore, the rear housing 200 has the air inlet 210 and the air outlet 220 to allow air to flow in and out of the internal region 800. In the embodiment shown in FIG. 1, the air inlet 210 and the air outlet 220 are disposed on opposite sides of the rear housing 200, and there are two air inlets 210. However, in different embodiments, the air inlet 210 and the air outlet 220 are not limited to being on opposite sides, and the positions and quantities of the air inlet 210 and the air outlet 220 can be adjusted according to the needs.

The fan 300 is positioned within the internal region 800 and close to the air inlet 210 or the air outlet 220. The fan 300 is configured to drive air through the air inlet 210 into the internal region 800, and through the air outlet 220 out of the internal region 800, forming the airflow pathway 700 between the air inlet 210 and the air outlet 220. More specifically, in the embodiment shown in FIG. 1, the fan 300 is positioned within the internal region 800 and close to the air outlet 220, driving air to flow through the air outlet 220 by expelling air from the internal region 800 through the air outlet 220. However, in different embodiments, the fan 300 may be positioned close to the air inlet 210, driving air to flow through the air inlet 210 by sucking air from the exterior of the display device 900 into the air inlet 210.

The flow-guiding structure 400 is positioned within the internal region 800 and along the airflow pathway 700. The flow-guiding structure 400 may move to allow air to selectively flow through a portion of the airflow pathway 700; that is, the movement of the flow-guiding structure 400 increases the amount of air passing through a portion of the airflow pathway 700 (defined as “open”) and reduces the amount of air passing through another portion of the airflow pathway 700 (defined as “closed”). Such movement mode of the flow-guiding structure 400 enables the user to adjust the distribution of the airflow pathway 700 in the display device 900 based on usage requirements, directing airflow to the area requiring heat dissipation enhancement. From another perspective, the flow-guiding structure 400 may move to alter the airflow pathway 700.

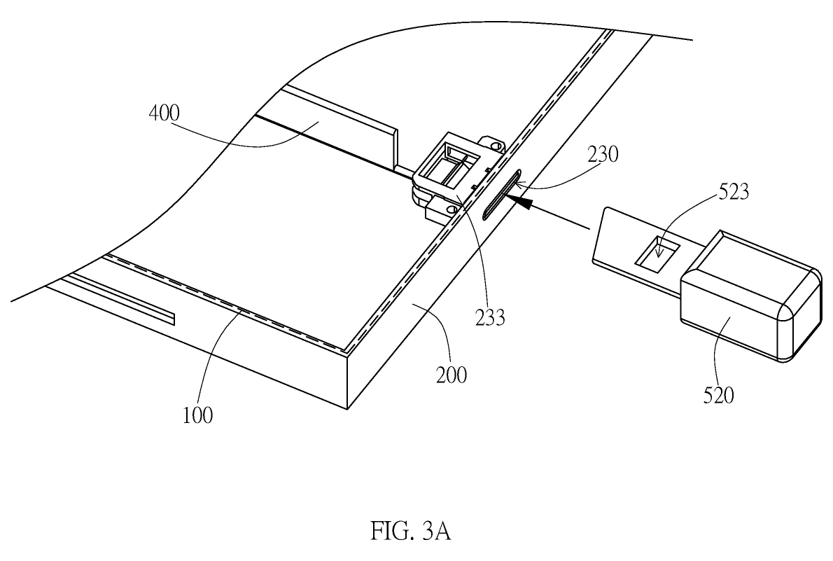

In an embodiment of the present invention, the flow-guiding structure 400 may be partially exposed to the exterior of the rear housing 200 for the user to apply force to make the flow-guiding structure 400 move, thus allowing air to selectively flow through a portion of the airflow pathway 700. However, in another embodiment, the display device 900 may further include an operating component to facilitate the user to apply force. In the embodiment shown in FIG. 2, the operating component 510 is positioned on the rear housing 200 and extends through the rear housing 200, wherein an end of the operating component 510 contacts the flow-guiding structure 400 to drive the flow-guiding structure 400 to move. In addition, the operating component 510 may be designed to be removable or nonremovable from the rear housing 200 based on manufacturing or usage requirements.

Specifically, in the embodiment shown in FIG. 2, the operating component 510 is an embedded component which is nonremovable from the rear housing 200. The embedded component, serving as the operating component 510, is secured to the rear housing 200 and includes a protruding part 511 and an inner part 512. The protruding part 511 is located outside the rear housing 200 and can be operated from the exterior of the rear housing 200; the inner part 512 is located within the internal region 800 and can contact the flow-guiding structure 400. The protruding part 511 of the embedded component may be a knob, a lever, a button, or the like, but not limited thereto. The user may operate the protruding part 511 through, for example, rotating, toggling, pressing, etc., to drive the flow-guiding structure 400 to move.

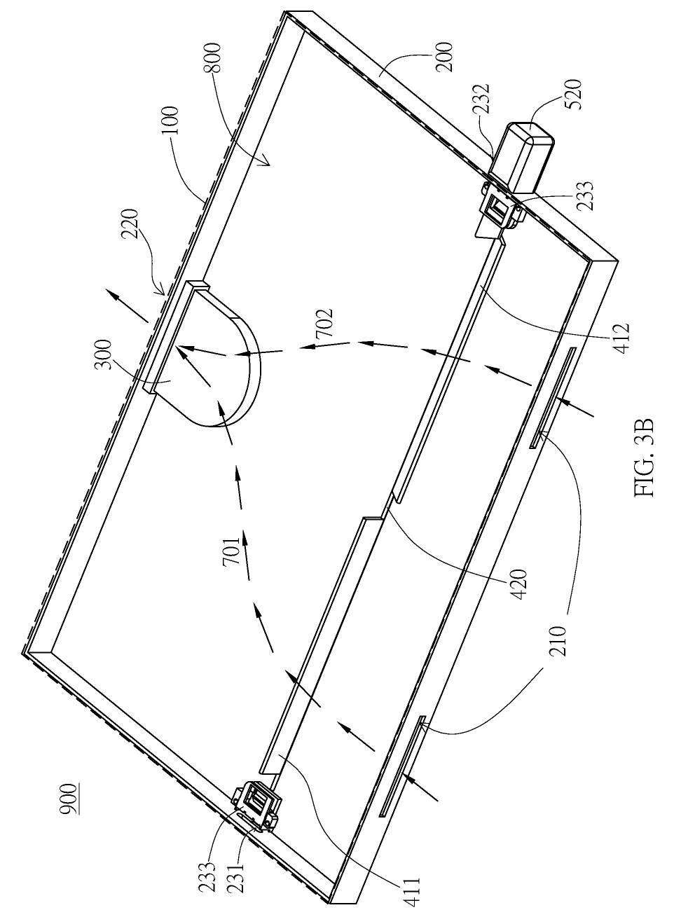

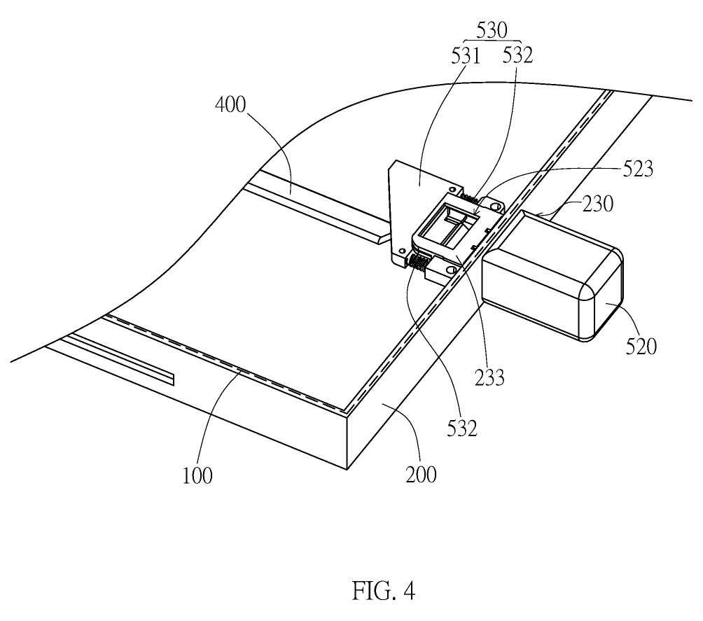

As shown in FIG. 3A, in another embodiment of the present invention, the operating component 520 is a removable plug removable from the rear housing 200. Correspondingly, the rear housing 200 has a slot 230 to insert the removable plug serving as the operating component 520, thereby securing the removable plug to the rear housing 200. Specifically, an end for insertion of the removable plug, serving as the operating component 520, may feature a loop 523; correspondingly, a hook 233 may be positioned on the inner side of the rear housing 200 close to the slot 230. After the removable plug, serving as the operating component 520, is inserted into the slot 230, the loop 523 will be secured by the hook 233. Regarding other methods to secure the removable plug serving as the operating component 520, in a variant embodiment (not shown in the figures), a hook may be positioned on the end for insertion of the removable plug, and a loop may be positioned on the inner side of the rear housing 200, but not limited thereto.

The removable plug, serving as the operating component 520, may drive the flow-guiding structure 400 to move in different directions based on its insertion positions on the display device 900. For example, as shown in FIG. 3B, the display device 900 may include an operating component 520 and two slots 231 and 232. When the operating component 520 is inserted into the slot 231, the flow-guiding structure 400 is pushed along a certain direction to allow a portion of the airflow pathway 701 to be open; when the operating component 520 is inserted into the other slot (not shown in the figures), i.e. the slot 232, the flow-guiding structure 400 is pushed along another direction to allow another portion of the airflow pathway 702 to be open.

As shown in FIG. 4, in another embodiment of the present invention, the display device 900 further includes a driving component 530. The driving component 530 is positioned within the internal region 800 and in contact with the removable plug (serving as the operating component 520) and the flow-guiding structure 400, respectively. The operating component 520 may drive the flow-guiding structure 400 to move via the driving component 530; that is, the operating component 520 indirectly drives the flow-guiding structure 400. The rear housing 200 includes the slot 230 (refer to FIG. 3A) for inserting and securing the operating component 520. Similar to the embodiment shown in FIG. 3A, the end of the operating component 520 for insertion may feature a loop 523; correspondingly, a hook 233 may be positioned on the inner side of the rear housing 200 close to the slot 230. After the operating component 520 is inserted into the slot 230, the loop 523 of the operating component 520 will be secured by the hook 233. For different designs (not shown in the figures), a hook may be positioned on the driving component 530, but not limited thereto.

Specifically, as shown in FIG. 4, the driving component 530 may include a cam 531 and a tension spring 532, wherein the tension spring 532 is positioned between the cam 531 and the rear housing 200. The cam 531 is pushed by the operating component 520 and moves along the elongating direction of the tension spring 532, thereby driving the flow-guiding structure 400. After the operating component 520 is removed, the cam 531 is pulled by the spring force of the tension spring 532 to move in the opposite direction; in the meantime, the cam 531 does not apply force to move the flow-guiding structure 400, thus restoring the flow-guiding structure 400 to its original position. To facilitate the movement of the flow-guiding structure 400, other components (not shown in the figures), including but not limited to springs, shafts, and fastening structures, may be positioned near the flow-guiding structure 400 and the rear housing 200.

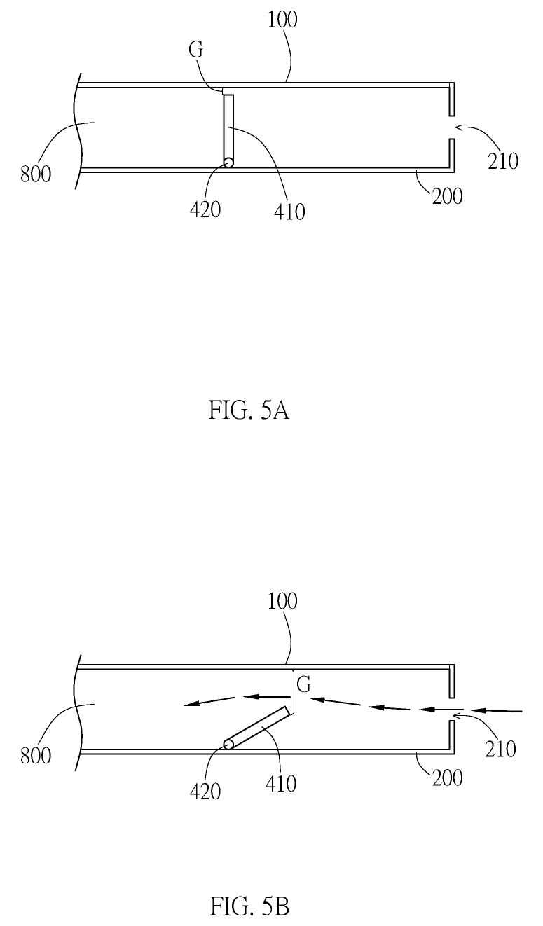

In another embodiment of the present invention, the flow-guiding structure 400 includes a longitudinal sheet 410. The longitudinal sheet 410 is a thin plate having a substantially rectangular shape, which is made of metal, plastic, etc., but not limited thereto. The movement mode of the longitudinal sheet 410 includes but is not limited to translation, rotation, and so on. For example, as shown in FIG. 5A, the longitudinal sheet 410 may be secured on a pivot axis 420. The pivot axis 420 is positioned within the internal region 800, allowing the longitudinal sheet 410 to rotate around the pivot axis 420. As shown in FIG. 5B, there is a gap G between the longitudinal sheet 410 and the display panel 100. When the longitudinal sheet 410 is driven to rotate, the gap G may increase to allow the airflow pathway 700 to be open. In a different design, to facilitate the movement of the longitudinal sheet 410, the flow-guiding structure 400 may further include other components (not shown in the figures), including but not limited to springs, shafts, and fastening structures, etc.

In another embodiment of the present invention, the flow-guiding structure 400 of the display device 900 includes at least two longitudinal sheets 410. The longitudinal sheets 410 are configured to move independently of each other; that is, driving one of the longitudinal sheets 410 to move may not accompany the movement of another longitudinal sheet 410.

In another embodiment of the present invention, the flow-guiding structure 400 of the display device 900 includes at least two longitudinal sheets 410. The longitudinal sheets 410 are interconnected and configured to move together; that is, driving one of the longitudinal sheets 410 to move may cause another longitudinal sheet 410 to move simultaneously.

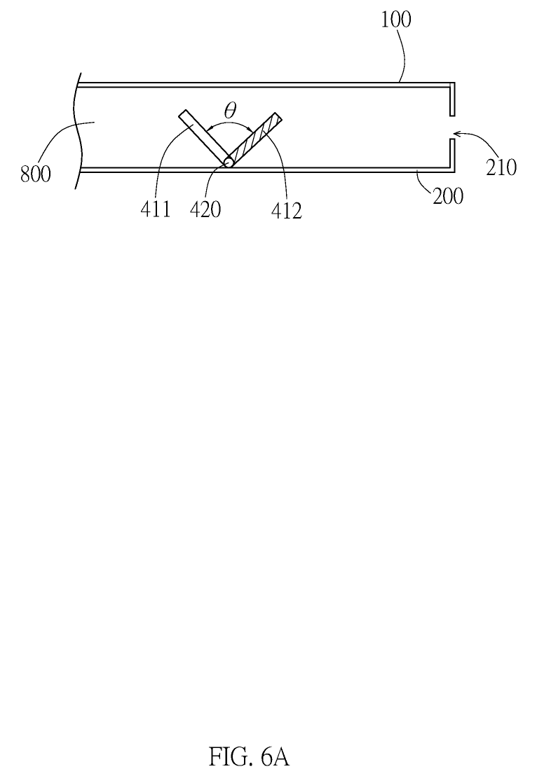

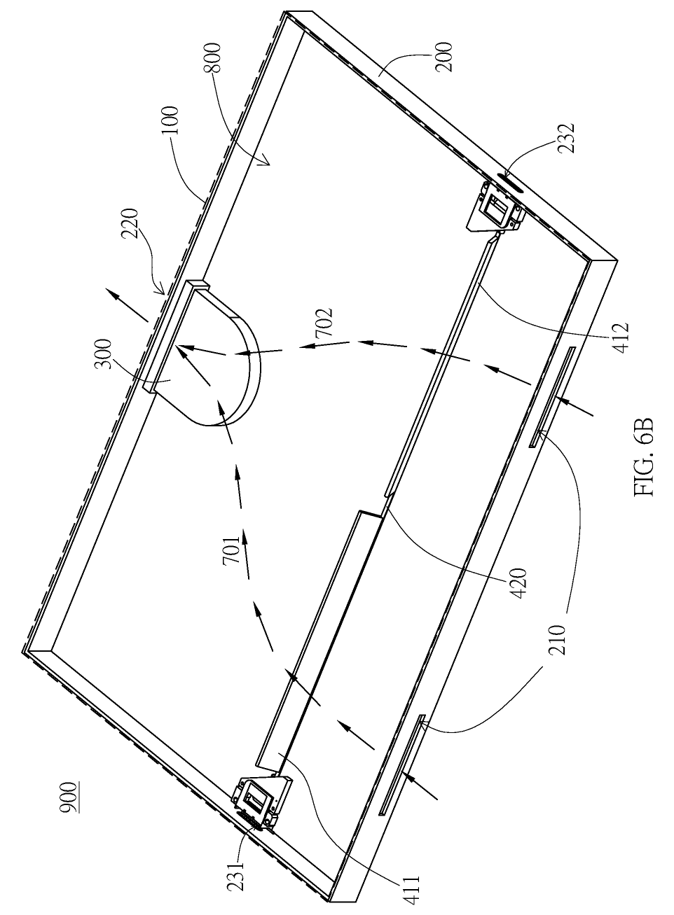

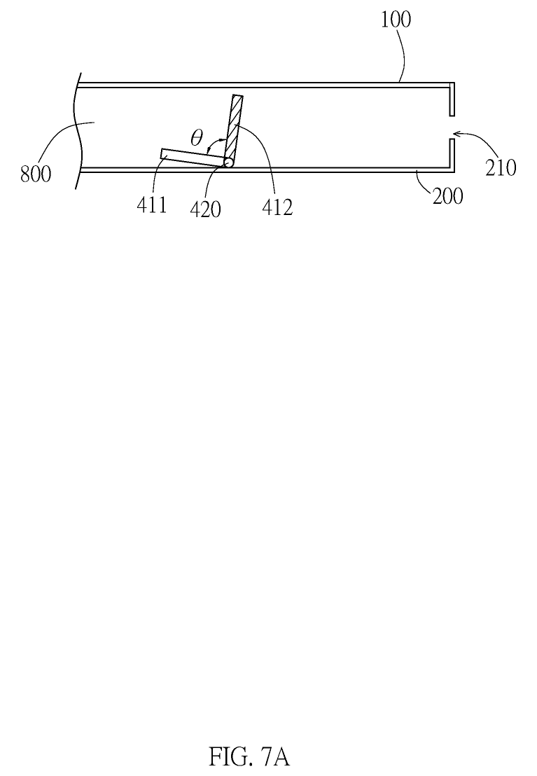

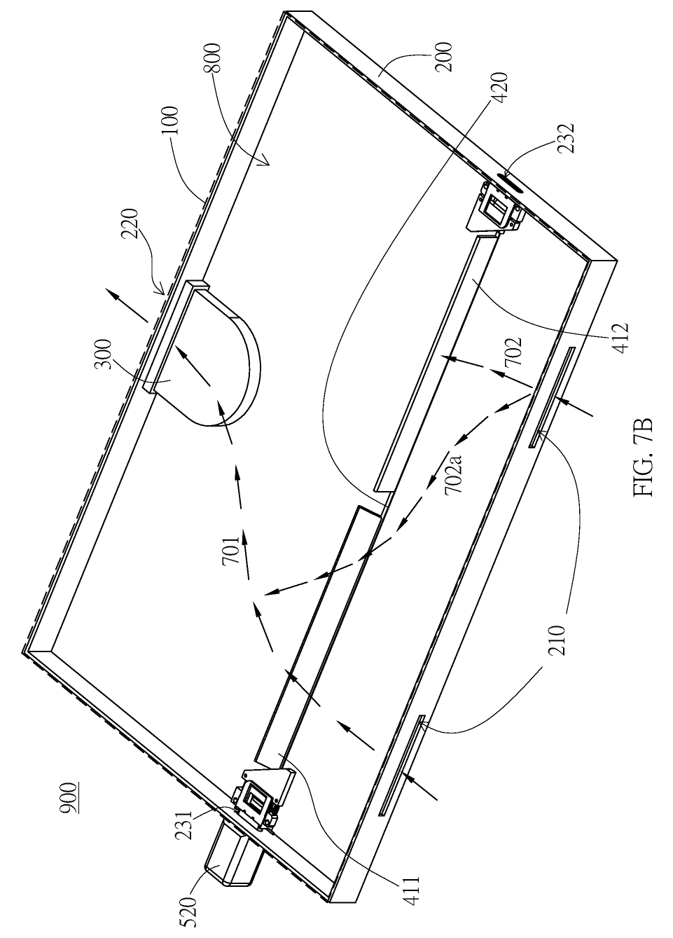

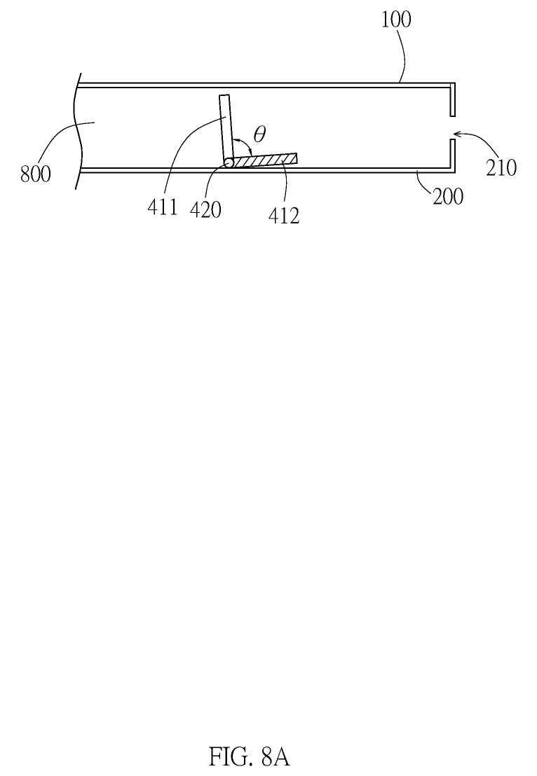

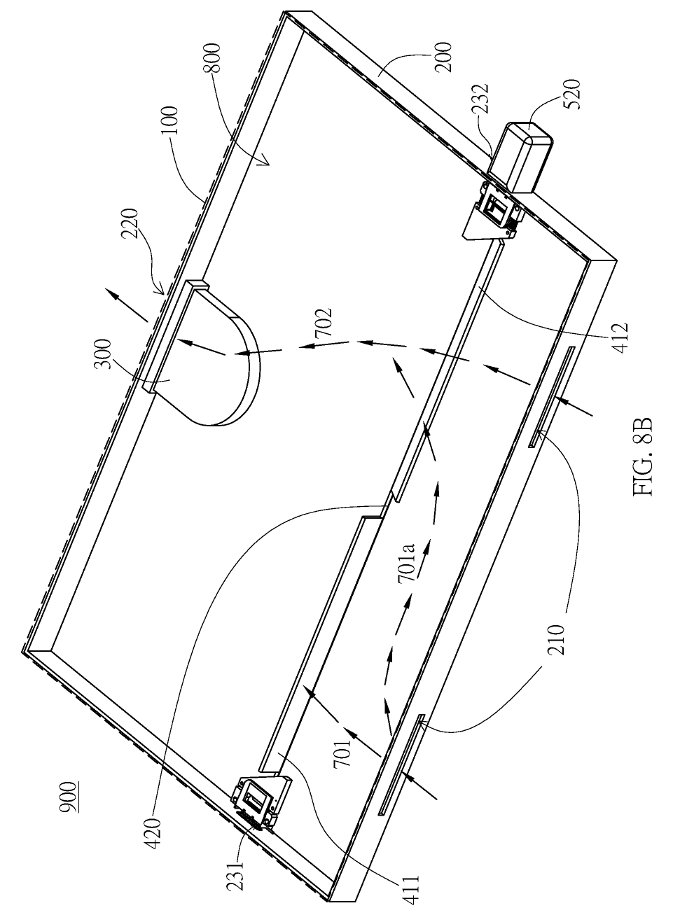

As shown in FIGS. 6A and 6B, in another embodiment of the present invention, the flow-guiding structure 400 of the display device 900 includes two longitudinal sheets 411 and 412. The two longitudinal sheets 411 and 412 form a predetermined angle θ therebetween, wherein the predetermined angle θ may be a fixed value between 0° and 180°, for example, 60°, 90° or 120°. In practical applications, based on the specific structural dimensions of the display device 900, the optimal value of the predetermined angle θ may be adjusted as needed. The two longitudinal sheets 411 and 412 are configured to move together. When the flow-guiding structure 400 is not driven, the two longitudinal sheets 411 and 412 are both in the initial positions, allowing all airflow pathway 701 and 702 to be open to the same extent.

A movement mode of the longitudinal sheets 411 and 412 is shown in FIGS. 7A and 7B. One of the longitudinal sheets 411 allows a portion of the airflow pathway, indicated by airflow pathway 701, to be open, and the other longitudinal sheet 412 causes another portion of the airflow pathway, indicated by airflow pathway 702, to be closed (in the meantime, the airflow passes through a variant airflow pathway 702a). As shown in FIGS. 8A and 8B, the above movement mode of the longitudinal sheets 411 and 412 may be operated in the opposite manner; therefore, the previously open portion of the airflow pathway 701 becomes closed (in the meantime, the airflow passes through a variant airflow pathway 701a), and the previously closed portion of the airflow pathway 702 becomes open. Specifically, the two longitudinal sheets 411 and 412 may be secured on a pivot axis 420. The pivot axis 420 is positioned within the internal region 800, allowing the longitudinal sheets 411 and 412 to rotate around the pivot axis 420 within the internal region 800. In addition, the two longitudinal sheets 411 and 412 may be driven through the operating component 520 and the driving component 530 as shown in FIG. 4. Preferably, an end side of the cam 531 of the driving component 530 features an oblique surface, and an end side of each of the two longitudinal sheets 411 and 412 also features an oblique surface. When the cam 531 is pushed by the operating component 520 and moves, the oblique surface on an end side of the cam 531 abuts the oblique surface on an end side of the longitudinal sheet 411 or 412, thereby driving the longitudinal sheet 411 or 412 to rotate around the pivot axis 420, but is not limited thereto.

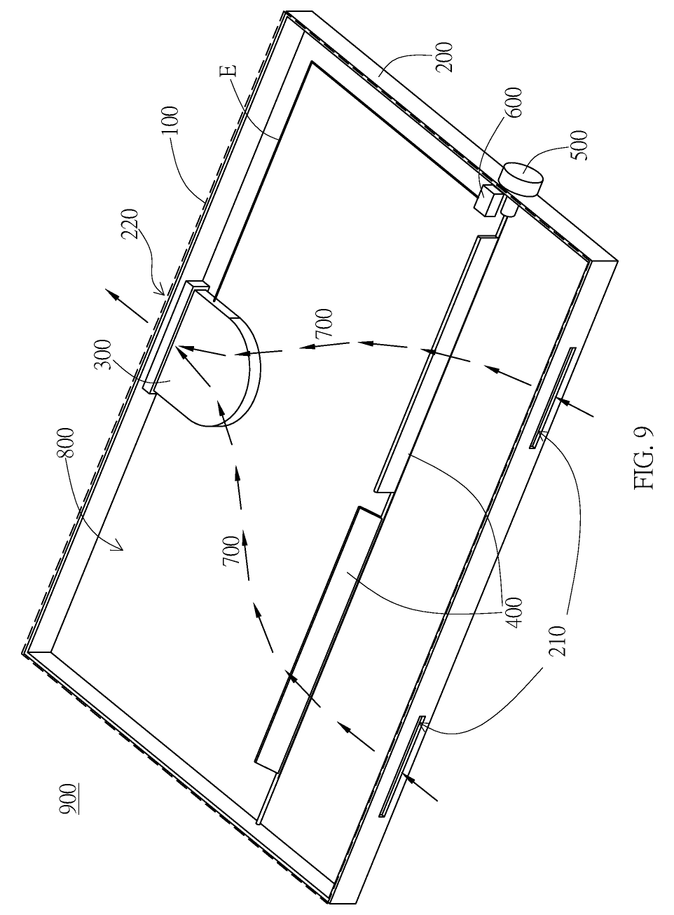

As shown in FIG. 9, in another embodiment of the present invention, the display device 900 further includes a sensor 600. The sensor 600 is positioned within the internal region and close to the operating component 500, wherein the sensor 600 is electrically connected to the fan 300 via a wiring E. The sensor 600 is configured to sense the movement of the operating component 500, thereby adjusting the rotation speed of the fan 300 according to the corresponding variations of the airflow pathway 700. For example, when the flow-guiding structure 400 is not driven, the operating component 500 stays at the initial position, and the fan 300 has a first rotation speed; when the operating component 500 moves to drive the flow-guiding structure 400 to allow air to selectively flow through a portion of the airflow pathway 700, the fan 300 has a second rotation speed, wherein the second rotation speed is lower than the first rotation speed. In a different design, the second rotation speed may be greater than the first rotation speed, or the fan 300 may have multi-stage rotation speeds. Based on the above settings, the rotation speed of the fan 300 can be adjusted according to different airflow pathways 700, thereby enhancing energy efficiency and reducing noise.

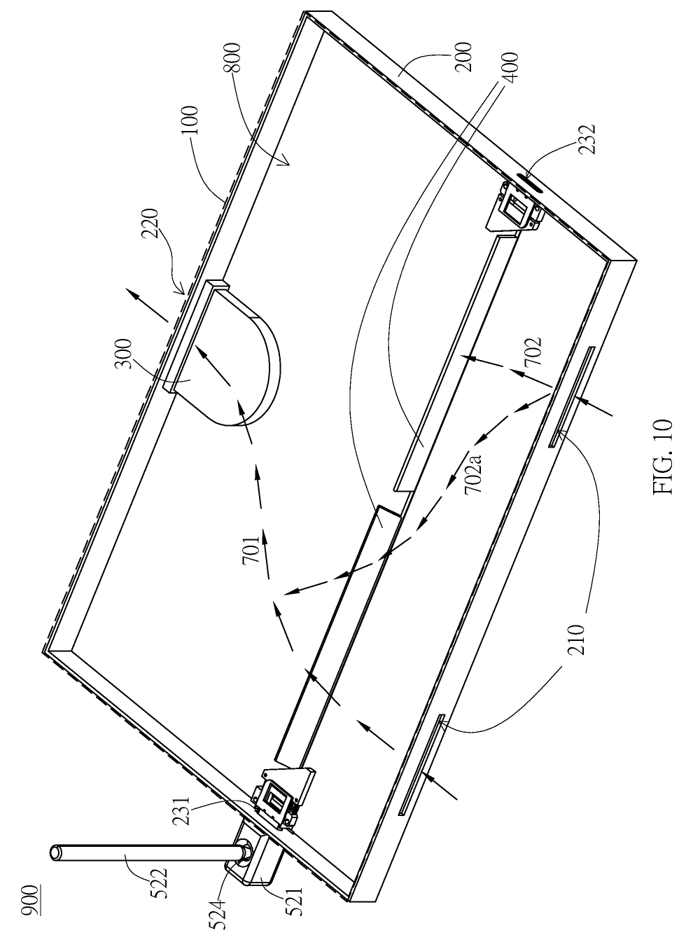

In another embodiment of the present invention, the display panel 100 of the display device 900 includes a touch screen. As shown in FIG. 10, the operating component 521 of the display device 900 may be a stylus holder, and a holding cavity 524 of the operating component 521 is configured to hold a stylus 522 compatible with the touch screen. For example, similar to the embodiment shown in FIGS. 7B and 8B, the rear housing 200 of the display device 900 may include two slots 231 and 232. When the stylus holder, serving as the operating component 520, is inserted into the slot 231 located to the left of the user, the flow-guiding structure 400 is pushed along a direction that allows the airflow pathway 701 located on the left to be open and causes the airflow pathway 702 located on the right to be closed (in the meantime, the airflow passes through a variant airflow pathway 702a). Conversely, when the stylus holder, serving as the operating component 520, is inserted into the slot 232 located to the right of the user, the flow-guiding structure 400 is pushed along another direction that causes the airflow pathway 701 located on the left to be closed and allows the airflow pathway 702 located on the right to be open. The flow-guiding structure 400 as shown in this embodiment may be operated in other movement modes and is not limited thereto. In addition, the stylus holder, serving as the operating component 520, may directly contact the flow-guiding structure 400 or indirectly contact the flow-guiding structure 400 via the driving component 530 as shown in FIG. 4, but is not limited thereto.

Specifically, the user may drive the flow-guiding structure in the display device by positioning the stylus holder in the slot on the dominant hand side, directing airflow to the area near the dominant hand side and thereby enhancing heat dissipation. Since the user may frequently touch the area near the dominant hand side of the display device, lowering the temperature of the area near the dominant hand side can significantly enhance comfort while using the display device.

The display device provided by the present invention can be operated to move the flow-guiding structure in order to concentrate airflow to pass through specific areas requiring heat dissipation enhancement, thereby achieving effective zoned cooling. The display device provided by the present invention can be equipped with components externally operated by the user in order to drive the flow-guiding structure inside the display device; or, the display device may also be equipped with sensors to adjust the rotation speed of the fan. These settings facilitate optimal cooling, leading to reduced noise and energy consumption while improving the user experience.

The present invention has been illustrated by the above embodiments. However, the above embodiments are only exemplary and are not to be regarded as limiting. Based on different designs, some components in one embodiment may be applied to another embodiment. For example, the embedded component, serving as the operating component 510, may be applied to the display device 900 as shown in FIGS. A and 6B, but is not limited thereto. The present invention is defined by the scope of the appended patent claims. Various changes and modifications to the present invention can be made by a person having ordinary skill in the art without departing from the spirit of the present invention, and that various changes and modifications fall within the scope of the present invention as defined by the appended patent claims.

What is claimed is:

1. A display device, comprising:
a display panel;
a rear housing positioned on a rear side of the display panel, wherein the rear housing and the display panel together define an internal region therebetween, and the rear housing has an air inlet and an air outlet;
a fan positioned within the internal region and close to the air inlet or the air outlet, wherein the fan is configured to drive air to flow through the air inlet and the air outlet, forming an airflow pathway between the air inlet and the air outlet; and
a flow-guiding structure movably positioned within the internal region and along the airflow pathway, wherein the flow-guiding structure is configured to move to allow air to selectively flow through a portion of the airflow pathway.

2. The display device of claim 1, further comprising an operating component, wherein an end of the operating component extends through the rear housing to contact the flow-guiding structure in order to drive the flow-guiding structure to move.

3. The display device of claim 2, wherein the operating component is an embedded component nonremovable from the rear housing, and the operating component includes:
a protruding part located outside the rear housing for operation, and
an inner part located within the internal region and in contact with the flow-guiding structure.

4. The display device of claim 2, wherein the operating component is a removable plug removable from the rear housing, and the rear housing has a slot configured corresponding to the flow-guiding structure;
the removable plug is configured to be insert into or separate from the slot;
wherein, when the removable plug is inserted into the slot, the removable plug is in contact with the flow-guiding structure in order to drive the flow-guiding structure to move.

5. The display device of claim 2, wherein the operating component is a removable plug removable from the rear housing, the rear housing has a slot, and the removable plug is configured to contact a driving component positioned within the internal region when inserted into the slot,
wherein the driving component directly contacts the flow-guiding structure, and the removable plug drive the flow-guiding structure to move via the driving component.

6. The display device of claim 1, wherein the flow-guiding structure comprises a longitudinal sheet.

7. The display device of claim 1, wherein the flow-guiding structure comprises at least two longitudinal sheets, and the longitudinal sheets are configured to move independently of each other; or, the longitudinal sheets are interconnected and configured to move together.

8. The display device of claim 7, wherein the flow-guiding structure comprises two longitudinal sheets,
wherein the two longitudinal sheets form a predetermined angle therebetween, and the predetermined angle lies between 0° and 180°;
wherein the two longitudinal sheets are configured to move to cause a portion of the airflow pathway to be closed with one of the two longitudinal sheets while allowing another portion of the airflow pathway to be open with the other of the two longitudinal sheets.

9. The display device of claim 2, further comprising a sensor positioned within the internal region to sense a movement of the operating component, wherein the sensor is electrically connected to the fan to adjust a rotation speed of the fan.

10. The display device of claim 1, wherein the display panel includes a touch screen;
the display device comprises a stylus compatible with the touch screen; and
the display device further comprises an operating component, wherein an end of the operating component extends through the rear housing to contact the flow-guiding structure in order to drive the flow-guiding structure to move; another end of the operating component has a holding cavity to hold the stylus.

11. A display device, comprising:
a display panel;
a rear housing positioned on a rear side of the display panel, wherein the rear housing and the display panel together define an internal region therein, and the rear housing has an air inlet and an air outlet;
a fan positioned within the internal region and close to the air inlet or the air outlet, wherein the fan is configured to drive air to flow through the air inlet and the air outlet, forming an airflow pathway between the air inlet and the air outlet; and
a flow-guiding structure movably positioned within the internal region and is configured to move to alter the airflow pathway.

12. The display device of claim 11, further comprising an operating component, wherein an end of the operating component extends through the rear housing to contact the flow-guiding structure in order to drive the flow-guiding structure to move.

13. The display device of claim 12, wherein the operating component is an embedded component nonremovable from the rear housing, and the operating component includes:
a protruding part located outside the rear housing for operation, and
an inner part located within the internal region and in contact with the flow-guiding structure.

14. The display device of claim 12, wherein the operating component is a removable plug removable from the rear housing, and the rear housing has a slot configured corresponding to the flow-guiding structure;
the removable plug is configured to be insert into or separate from the slot;
wherein, when the removable plug is inserted into the slot, the removable plug is in contact with the flow-guiding structure in order to drive the flow-guiding structure to move.

15. The display device of claim 12, wherein the operating component is a removable plug removable from the rear housing, the rear housing has a slot, and the removable plug is configured to contact a driving component positioned within the internal region when inserted into the slot,
wherein the driving component directly contacts the flow-guiding structure, and the removable plug drive the flow-guiding structure to move via the driving component.

16. The display device of claim 11, wherein the flow-guiding structure comprises a longitudinal sheet.

17. The display device of claim 11, wherein the flow-guiding structure comprises at least two longitudinal sheets, and the longitudinal sheets are configured to move independently of each other; or, the longitudinal sheets are interconnected and configured to move together.

18. The display device of claim 17, wherein the flow-guiding structure comprises two longitudinal sheets,
wherein the two longitudinal sheets form a predetermined angle therebetween, and the predetermined angle lies between 0° and 180°;
wherein the two longitudinal sheets are configured to move to cause a portion of the airflow pathway to be closed with one of the two longitudinal sheets while allowing another portion of the airflow pathway to be open with the other of the two longitudinal sheets.

19. The display device of claim 12, further comprising a sensor positioned within the internal region to sense a movement of the operating component, wherein the sensor is electrically connected to the fan to adjust a rotation speed of the fan.

20. The display device of claim 11, wherein the display panel includes a touch screen;
the display device comprises a stylus compatible with the touch screen; and
the display device further comprises an operating component, wherein an end of the operating component extends through the rear housing to contact the flow-guiding structure in order to drive the flow-guiding structure to move; another end of the operating component has a holding cavity to hold the stylus.
